(19) United States
(12) Patent Application Publication
(10) Pub. No.: US 2024/0112975 A1
(43) Pub. Date: Apr. 4, 2024

(54) ELECTRONIC DEVICES AND METHODS OF MANUFACTURING ELECTRONIC DEVICES

(71) Applicant: Amkor Technology Singapore Holding Pte. Ltd., Valley Point #12-03 (SG)

(72) Inventors: Kwang Seok PARK, Seoul (KR); Won Bae BANG, Incheon (KR); Seo Yoon CHANG, Incheon (KR)

(73) Assignee: Amkor Technology Singapore Holding Pte. Ltd., Valley Point #12-03 (SG)

(21) Appl. No.: 17/958,965

(22) Filed: Oct. 3, 2022

(51) Int. Cl. H01L 23/31; H01L 21/56; H01L 23/00

(52) U.S. Cl. CPC H01L 23/3185; H01L 21/56; H01L 21/561; H01L 23/3192; H01L 24/32; H01L 24/48; H01L 27/14601

(57) ABSTRACT

In one example, an electronic device includes a substrate including a substrate first side, a conductive structure, and a substrate sidewall on the substrate first side. The substrate sidewall forms a perimeter, the substrate first side within the perimeter defines a substrate base, and the substrate sidewall and the substrate base form a substrate cavity. An electronic component includes a component first side, a component second side, and a component lateral side. The electronic component is disposed over a first portion of the substrate base within the substrate cavity and is coupled to the conductive structure. An encapsulant encapsulates at least a portion of the component lateral side, and a lid is over at least a portion of the component first side. At least a portion of the component first side is devoid of the encapsulant. Other examples and related methods are also disclosed herein.

### CROSS-REFERENCE TO RELATED APPLICATIONS

Not applicable.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A, 2B, 2C, 2D, 2E, 2F, and 2G show cross-sectional views of an example method for manufacturing an example electronic device.

FIG. 3 shows a cross-sectional view of an example electronic device.

FIGS. 4A, 4B, and 4C show cross-sectional views of an example method for manufacturing an example electronic device.

FIG. 5 shows a cross-sectional view of an example electronic device.

FIGS. 6A, 6B, 6C, and 6D show cross-sectional views of an example method for manufacturing an example electronic device.

FIG. 7 shows a cross-sectional view of an example electronic device.

FIGS. 8A, 8B, 8C, and 8D shows cross-sectional views of an example method for manufacturing an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. Crosshatching lines may be used throughout the figures to denote different parts but not necessarily to denote the same or different materials. Throughout the present disclosure, like reference numbers denote like elements. Accordingly, elements with like element numbering may be shown in the figures but may not be necessarily repeated herein for the sake of clarity.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. As used herein, the term coupled can refer to an electrical coupling or a mechanical coupling. Similarly, the terms “over” or “on” may be used to describe two elements directly contacting each other or describe two elements indirectly connected by one or more other elements.

### DESCRIPTION

In an example, an electronic device includes a substrate including a substrate first side, a conductive structure, and a substrate sidewall on the substrate first side. The substrate sidewall forms a perimeter, the substrate first side within the perimeter defines a substrate base, and the substrate sidewall and the substrate base form a substrate cavity. An electronic component includes a component first side, a component second side opposite to the component first side, and a component lateral side connecting the component first side to the component second side. The electronic component is disposed over a first portion of the substrate base within the substrate cavity and is coupled to the conductive structure. An encapsulant encapsulates at least a portion of the component lateral side, and a lid is over at least a portion of the component first side. At least a portion of the component first side is devoid of the encapsulant.

In an example, an electronic device includes a substrate comprising a substrate base, a substrate sidewall at a perimeter of the substrate base, and a conductive structure, wherein the substrate base and the substrate sidewall define a substrate cavity. An electronic component is disposed over the substrate base in the substrate cavity and coupled to the conductive structure, the electronic component comprising a component first side distal to the substrate base and a component lateral side. An encapsulant is over at least a portion of the component lateral side, wherein at least a first portion of the component first side is free of the encapsulant. A lid overlies at least the first portion of the component first side.

In an example, a method of manufacturing an electronic device includes providing a substrate including a substrate base, a substrate sidewall at a perimeter of the substrate base, and a conductive structure, wherein the substrate base and the substrate sidewall define a substrate cavity. The method includes providing a first electronic component comprising a component first side, a component second side opposite to the component first side, and a component lateral side connecting the component first side to the component second side. The method includes disposing the first electronic component over the substrate base and in the substrate cavity. The method includes coupling an internal interconnect between the first electronic component and the conductive structure. The includes providing an encapsulant over at least a portion of the component lateral side. The method includes providing a lid overlying at least a first portion of the component first side.

Other examples are included in the present disclosure. Such examples may be found in the figures, in the claims, or in the description of the present disclosure.

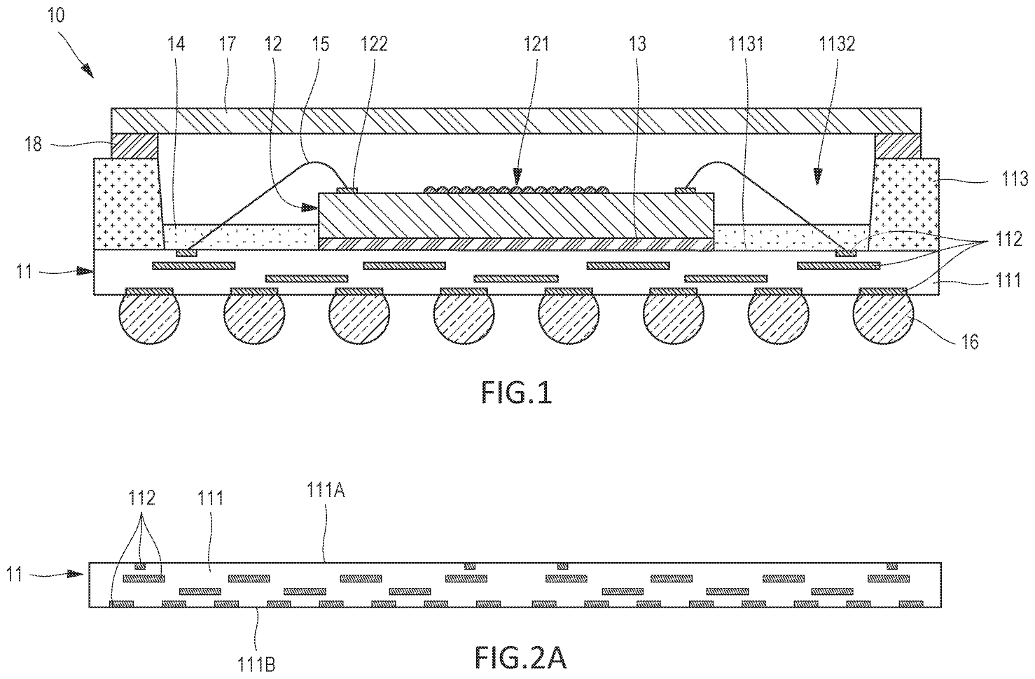

FIG. 1 shows a cross-sectional view of an example electronic device 10. In the example shown in FIG. 1, electronic device 10 can comprise substrate 11, electronic component 12, adhesives 13 and 18, encapsulant 14, internal interconnects 15, external interconnects 16, and lid 17.

Substrate 11 can comprise dielectric structure 111, conductive structure 112, and substrate sidewall 113. Substrate sidewall 113 can define or form a perimeter of substrate cavity 1132. In some examples, electronic component 12 can comprise transceiver module 121 and component terminals 122.

Substrate 11, adhesives 13 and 18, encapsulant 14, internal interconnects 15, external interconnects 16, and lid 17 can comprise or be referred to as an electronic package or a package. The electronic package can protect electronic component 12 from exposure to external factors or environments. The electronic package can provide a coupling between electronic component 12 and external components or other electronic components.

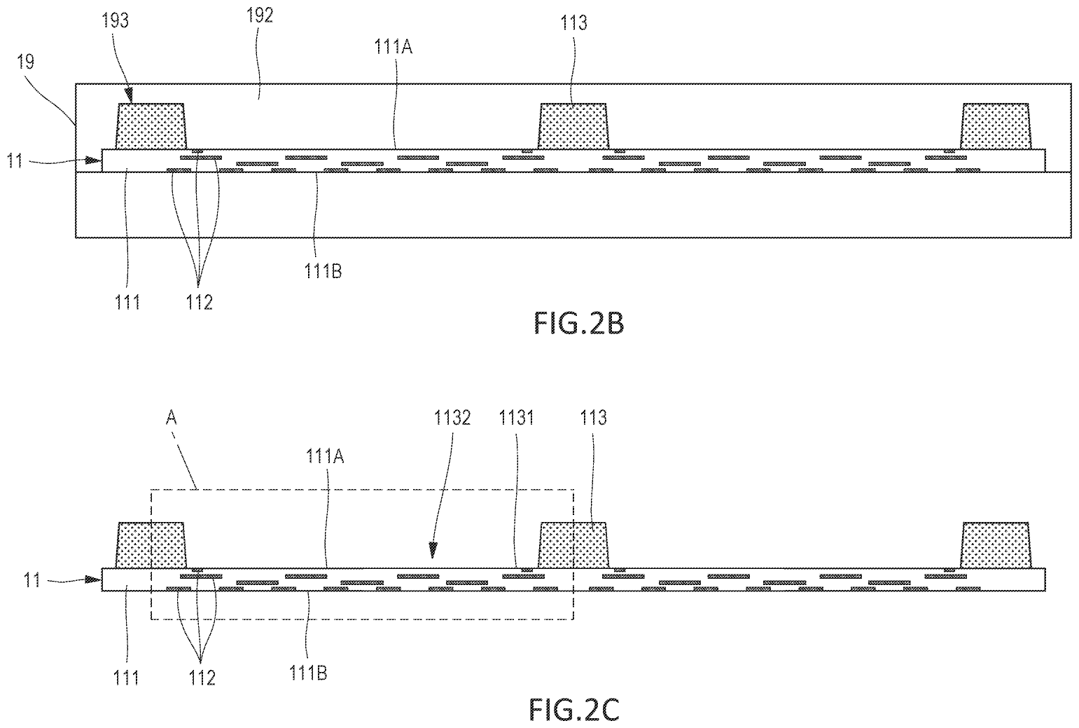

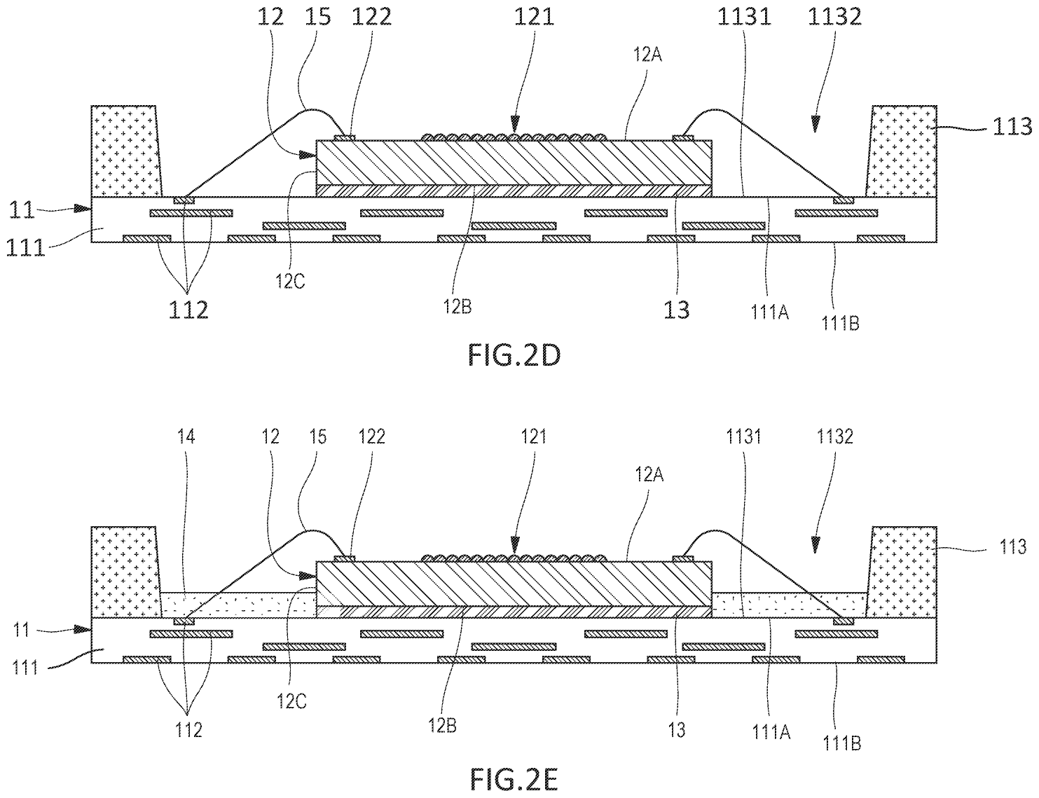

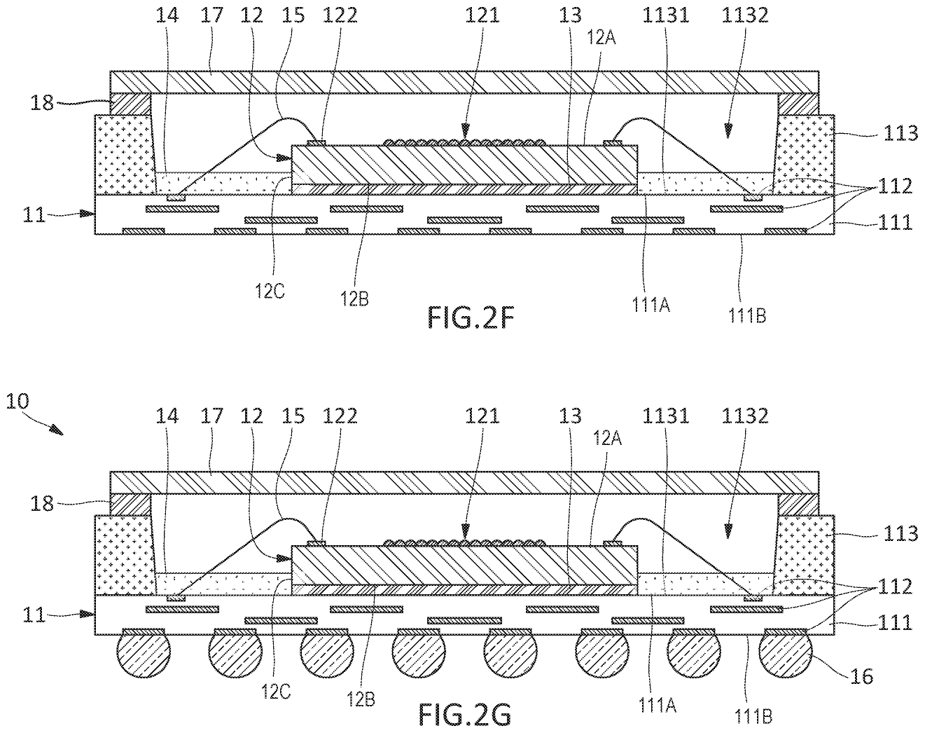

FIGS. 2A to 2G show cross-sectional views of an example method for manufacturing electronic device 10. FIG. 2A shows a cross-sectional view of electronic device 10 at an early stage of manufacture.

In the example shown in FIG. 2A, substrate 11 can be provided. In some examples, substrate 11 can comprise or be referred to as a printed circuit board (PCB) or a laminate substrate. In some examples, substrate 11 can comprise or be referred to as redistribution layer (RDL) substrate. In some examples, substrate 11 can be in the form of a strip, wafer, or panel for simultaneous production of multiple electronic devices 10. Substrate 11 can comprise dielectric structure 111 and conductive structure 112. In some examples, the thickness of substrate 11 can range from about 110 micrometers (μm) to about 1080 μm. Substrate 11 comprises a substrate first side 11A and a substrate second side 11B. In some examples, substrate first side 11A can be referred to as a top side or an upper side, and substrate second side 11B can be referred to as a bottom side or a lower side.

In some examples, dielectric structure 111 can comprise or be referred to one or more dielectrics, dielectric materials, dielectric layers, passivation layers, insulating layers, or protective layers. In some examples, dielectric structure 111 can have a structure where one or more preformed dielectric layers are stacked. In some examples, dielectric structure 111 can comprise polymer, polyimide (PI), benzocyclobutene (BCB), polybenzoxazole (PBO), bismaleimide triazine (BT), a molding material, phenolic resin, epoxy, silicone, or acrylate polymer. Dielectric structure 111 can be in contact with conductive structure 112. Parts of conductive structure 112 can be exposed from dielectric structure 111 (e.g., exposed portions of conductive structure 111 can be coupled to internal interconnects 15 or external interconnects 16). In some examples, dielectric structure 111 can maintain the shape of substrate 11 and can structurally support conductive structure 112. In some examples, dielectric structure 111 can be provided by spin coating, spray coating, printing, oxidation, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). In some examples, the thicknesses of dielectric structure 111 can range from about 10 μm to about 100 μm. The combined thickness of all layers of dielectric structure 111 can define the thickness of substrate 11.

In some examples, conductive structure 112 can comprise or be referred to as one or more conductors, conductive materials, conductive paths, conductive layers, redistribution layers, wiring layers, traces, vias, pads, substrate conductive structure, or UBMs. In some examples, one or more conductive layers may be interleaved with the dielectric layers of dielectric structure 111. In some examples, conductive structure 112 can comprise copper, aluminum, palladium, titanium, tungsten, titanium/tungsten, nickel, gold, or silver. In some examples, conductive structure 112 can be provided by sputtering, electroless plating, electrolytic plating, PVD, CVD, MOCVD, ALD, LPCVD, or PECVD. In some examples, part of conductive structure 112 can be exposed at the top side or at the bottom side of substrate 11. In some examples, conductive structure 112 can be coupled to internal interconnects 15 and external interconnects 16. Conductive structure 112 can transmit signals, currents, or voltages through substrate 11. In some examples, the thickness of conductive structure 112 can range from about 10 μm to about 100 μm. The thickness of conductive structure 112 can refer to individual layers of conductive structure 112.

In some examples, substrate 11 can be a pre-formed substrate. The pre-formed substrate can be manufactured prior to attachment to an electronic device and can comprise dielectric layers between respective conductive layers. The conductive layers can comprise an electrically conductive material such as, for example, copper and can be formed using an electroplating process. The dielectric layers can be non-photo-definable layers that can be attached as a pre-formed film rather than as a liquid and can include a resin with fillers such as strands, weaves, or other inorganic particles for rigidity or structural support. For non-photo-definable dielectric layers, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and the dielectric and conductive layers can be formed on the permanent core structure. In other examples, the pre-formed substrate can be a coreless substrate which omits the permanent core structure, and the dielectric and conductive layers can be formed on a sacrificial carrier that is removed after formation of the dielectric and conductive layers and before attachment to the electronic device. The pre-formed substrate can rereferred to as a printed circuit board (PCB) or a laminate substrate. Such pre-formed substrates can be formed through a semi-additive or modified-semi-additive process. In various examples, substrates in this disclosure can comprise pre-formed substrates.

In some examples, substrate 11 can be an RDL substrate. RDL substrates can comprise one or more conductive redistribution layers and one or more dielectric layers that (a) can be formed layer by layer over an electronic device to which the RDL substrate is electrically coupled, or (b) can be formed layer by layer over a carrier that can be removed after the electronic device is coupled to the RDL substrate. RDL substrates can be manufactured layer by layer as a wafer-level substrate on a round wafer in a wafer-level process or as a panel-level substrate on a rectangular or square panel carrier in a panel-level process. RDL substrates can be formed in an additive buildup process that can include one or more dielectric layers alternatingly stacked with one or more conductive layers that define respective conductive redistribution patterns or traces configured to collectively (a) fan-out electrical traces outside the footprint of the electronic device, or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process, which can include a photolithographic mask through which light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles that could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in other examples the dielectric materials of the RDL substrates can comprise one or more inorganic dielectric layers. Some examples of inorganic dielectric layer(s) can comprise silicon nitride (Si3N4), silicon oxide (SiO2), or silicon oxynitride (SiON). The inorganic dielectric layer(s) can be formed by growing the inorganic dielectric layers using an oxidation or nitridization process rather than using photo-defined organic dielectric materials. Such inorganic dielectric layers can be filler-fee, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can be referred to as a coreless substrate. In various examples, substrates in this disclosure can comprise RDL substrates.

FIGS. 2B and 2C show cross-sectional views of electronic device 10 at a later stage of manufacture. In the example shown in FIGS. 2B and 2C, substrate walls 113 (and thus substrate cavity 1132) can be provided over substrate 11. Referring to FIG. 2B, in some examples, substrate 11 is placed in a mold tool (or mold chase) 19 and a mold material is dispensed inside of mold tool 19. In some examples, an upper portion 192 of mold tool 19 can include or define a mold cavity 193 for forming substrate sidewall 113 on substrate 11. For example, the shape of mold cavity 193 corresponds to the shape of substrate sidewall 113. The mold material can be provided in mold cavity 193 to form substrate sidewall 113.

In the example shown in FIG. 2C, mold tool 19 is removed, thereby providing substrate sidewall 113 and substrate cavity 1132 over substrate 11. For example, substrate sidewall 113 and substrate base 1131 can define substrate cavity 1132. In some examples, substrate base 1131 can comprise or refer to the portion of the top side of substrate 11 located inside substrate sidewall 113 (e.g., substrate sidewall 113 may be located around or define the perimeter of substrate base 1131). In some examples, substrate sidewall 113 can comprise or be referred to as a stiffener, a dielectric layer, a mold compound layer, a laminate layer, or a ceramic layer. Substrate sidewall 113 can be provided at the edge of substrate 11. In some examples, substrate sidewall 113 can be provided continuously at the edge of substrate 11. In some examples, substrate sidewall 113 completely surrounds cavity 1132.

FIG. 2D shows a cross-sectional view of electronic device 10 at a later stage of manufacture. FIGS. 2D to 2G show enlarged cross-sectional views of part A shown in FIG. 2C.

In the example shown in FIG. 2D, electronic component 12 can be provided on substrate 11. Electronic component 12 can be provided on substrate base 1131 within substrate cavity 1132. Substrate cavity 1132 can accommodate electronic component 12 and internal interconnects 15. In some examples, the area (or footprint) of substrate base 1131 can be greater than the area (footprint) of electronic component 12. Electronic component 12 can comprise a component first side 12A, a component second side 12B opposite to component first side 12A, and a component lateral side 12C connecting component first side 12A to component second side 12B. Component first side 12A can also be referred to as a component top side or a component upper side, and component second side 12B can also be referred to as a component bottom side or a component lower side.

In some examples, electronic component 12 can be seated on substrate base 1131. Part of conductive structure 112 can be provided and exposed from substrate base 1131. Internal interconnects 15 can be coupled to conductive structure 112.

In some examples, substrate sidewall 113 can be provided outside internal interconnects 15. Substrate sidewall 113 can laterally surround electronic component 12. In some examples, substrate sidewall 113 can comprise polymer, a mold compound, epoxy, an epoxy molding compound, polyimide (PI), benzocyclobutene (BCB), polybenzoxazole (PBO), bismaleimide triazine (BT), a molding material, phenolic resin, silicone, or acrylate polymer. In some examples, the height of substrate sidewall 113, as measured from the top side of substrate 11, can range from about 100 μm to about 1000 μm, and the width of substrate sidewall 113, as measured between the interior surface of substrate sidewall 113 (i.e., the surface oriented toward electronic component 120) and the exterior surface of substrate sidewall 113 (i.e., the surface oriented away from electronic component 12) can range from about 500 μm to about 2000 μm. In some examples, the height of substrate sidewall 113 can be greater than the height of electronic component 12. In some examples, substrate 11 comprising dielectric structure 111, conductive structure 112, substrate sidewall 113, and substrate cavity 1132 can be referred to as a molded substrate or a cavity substrate.

Electronic component 12 can be coupled to substrate base 1131 through adhesive 13. In some examples, adhesive 13 can comprise a heat-curable adhesive, a light-curable adhesive, or a non-curable adhesive (e.g., a rubber-based adhesive, an acrylic adhesive, a vinyl alkyl ether-based adhesive, a silicone-based adhesive, a polyester-based adhesive, a polyamide-based adhesive, or a urethane-based adhesive).

In some examples, the bottom side of electronic component 12 can be attached to substrate base 1131 through adhesive 13, and the top side of electronic component 12 can be exposed. Transceiver module 121 and component terminals 122 can be provided on the top side 12A of electronic component 12. In some examples, electronic component 12 can comprise or be referred to a semiconductor die, a semiconductor chip, or a semiconductor package. In some examples, electronic component 12 can comprise an optical device, an optical sensor, an optical emitter, a complementary metal-oxide semiconductor (CMOS) image sensor (CIS), a sensor device, a transmitter device, or a laser device. In some examples, the height of electronic component 12 can range from about 60 μm to about 580 μm.

In some examples, transceiver module 121 can comprise or be referred to as a transmitter, a receiver, a transceiver structure, a sensor structure, an image sensor structure, or an optical sensor structure. In some examples, transceiver module 121 can comprise a micro-lens array, a color filter array, a laser emitter, or an image sensor. In some examples, transceiver module 121 can be part of electronic component 12, can be formed on electronic component 12, or can be coupled to electronic component 12. In some examples, transceiver module 121 can transmit an optical signal generated from electronic component 12 in a vertical direction or can receive an optical signal generated from an external component in a vertical direction. In some examples, the height of transceiver module 121 can range from about 0 μm to about 5 μm.

In some examples, component terminals 122 can comprise or be referred to as pads, lands, bond pads, UBMs, or bumps. In some examples, component terminals 122 can comprise copper, aluminum, palladium, titanium, tungsten, titanium/tungsten, nickel, gold, or silver. Component terminals 122 can be provided outside transceiver module 121. For example, component terminals 122 can be closer to the lateral side 12C of the electronic component 12 as compared to transceiver module 121. Component terminals 122 can be coupled to internal interconnects 15. Component terminals 122 and internal interconnects 15 can provide an electrical coupling between electronic component 12 and substrate 11. In some examples, the thicknesses of component terminals 122 can range from about 5 μm to about 50 μm.

In the example shown in FIG. 2D, internal interconnects 15 can be provided between component terminals 122 and substrate 11. In some examples, internal interconnects 15 can comprise or be referred to as wires or wirebonds. Internal interconnects 15 can couple electronic component 12 to conductive structure 112. For examples, internal interconnects 15 can be coupled to component terminals 122 and conductive structure 112. In some examples, internal interconnects 15 can be coupled to conductive structure 112 at the top side of substrate 11. In some examples, internal interconnects 15 can be coupled to component terminals 122 and conductive structure 112 by means of wire bonding. In some examples, internal interconnects 15 can comprise copper, aluminum, palladium, titanium, tungsten, titanium/tungsten, nickel, gold, or silver.

FIG. 2E shows a cross-sectional view of electronic device 10 at a later stage of manufacture. In the example shown in FIG. 2E, encapsulant 14 can be provided within substrate cavity 1132. In some examples, encapsulant 14 encapsulates a portion of substrate 1131 outside of the footprint of electronic component 12. In some examples, encapsulant 14 encapsulates (e.g., is over) at least a portion of component lateral side 12C but does not encapsulate (e.g., is not over) component first side 12A. That is, at least a portion of component first side 12A is devoid of encapsulant 14. In some examples, encapsulant 14 does not encapsulate (e.g., is not over) transceiver module 121. Encapsulant 14 can encapsulate substrate base 1131, part of internal interconnects 15, and part of electronic component 12. In some examples, encapsulant 14 can contact the lateral sides of electronic component 12 and the interior surface of substrate sidewall 113. In some examples, encapsulant 14 can comprise or be referred to as epoxy, resin, polymer, a mold compound, a protective material, or a mold material. In some examples, encapsulant 14 can be cured after being dispensed onto substrate base 1131. In some examples, encapsulant 14 can cover substrate base 1131 and part of substrate sidewall 113, thereby preventing, reducing, the generation or migration of foreign materials (e.g., fragments of solder mask or fragments of substrate sidewall 113). In some examples, encapsulant 14 can facilitate the inspection of foreign materials or particles present in substrate cavity 1132. That is, foreign materials or particles (particularly very small particles) are easier to detect on encapsulant 14 with inspection equipment than foreign materials or particles present on substrate base 1131 in the absence of encapsulant 14. In some examples, the thickness of encapsulant 14 can range from about 60 μm to about 580 μm. The thickness of encapsulant 14 can be less than the thickness of electronic component 12. In some examples, substrate sidewall 113 can block or prevent encapsulant 14 from flowing out of substrate cavity 1132 or off substrate 11.

FIG. 2F shows a cross-sectional view of electronic device 10 at a later stage of manufacture. In the example shown in FIG. 2F, lid 17 can be provided over substrate 11. Lid 17 can be coupled to substrate sidewall 113 through adhesive 18. In some examples, lid 17 can comprise or be referred to as a cover. Lid 17 can cover substrate cavity 1132. In some examples, lid 17 can have a greater area or (footprint) than substrate cavity 1132. In some examples, lid 17 can comprise a translucent, transparent, or transmissive material. For example, lid 17 can comprise glass. In some examples, lid 17 is configured such that an optical signal generated from electronic component 12 or an optical signal generated from an external component can permeate lid 17. That is, lid 17 comprises a material configured to transmit, transfer, or pass (e.g., into and/or out of electronic device 10) an optical signal. In some examples, lid 17 can prevent foreign materials or particles from entering substrate cavity 1132. In some examples, lid 17 can cover electronic component 12. Lid 17 (and substrate sidewall 113) can thus protect electronic component 12 from exposure to external factors or environments.

In some examples, adhesive 18 can comprise a heat-curable adhesive, a light-curable adhesive, or a non-curable adhesive (e.g., a rubber-based adhesive, an acrylic adhesive, a vinyl alkyl ether-based adhesive, a silicone-based adhesive, a polyester-based adhesive, a polyamide-based adhesive, or a urethane-based adhesive). In some examples, adhesive 18 can be provided on substrate sidewall 113, and cured by light (UV) after lid 17 is provided on adhesive 18, thereby fixing lid 17 to substrate sidewall 113.

FIG. 2G shows a cross-sectional view of electronic device 10 at a later stage of manufacture. In the example shown in FIG. 2G, external interconnects 16 can be provided on the bottom side of substrate 11. In some examples, external interconnects 16 can be coupled to exposed portions of conductive structure 112 on the bottom side of substrate 11. In some examples, external interconnects 16 can comprise or be referred to as solder balls, solder coated metal core balls (e.g., solder coated copper balls), pillars, pillars with solder caps, or bumps. External interconnects 16 can comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. In some examples, external interconnects 16 can be provided by forming a conductive material containing solder on the bottom side of substrate 11 through a ball-drop process and then performing a reflow process. External interconnects 16 can couple electronic device 10 to an external device. In some examples, the thickness of external interconnect 16 can range from about 20 μm to about 800 μm. In some examples, external interconnects 16 are not used and electronic device 10 can be coupled to an external device in a land grid array (LGA) configuration.

In the example shown in FIG. 2G, a singulation (e.g., dicing or sawing) process for separating substrate 11, which can be in the form of a strip or panel, into individual electronic devices 10 can be performed. In some examples, a sawing tool, such as a diamond blade or a laser beam, can be used during singulation to separate the individual electronic devices 10. In some examples, the sawing tool can cut through substrate 11 and/or through substrate sidewall 113 during singulation.

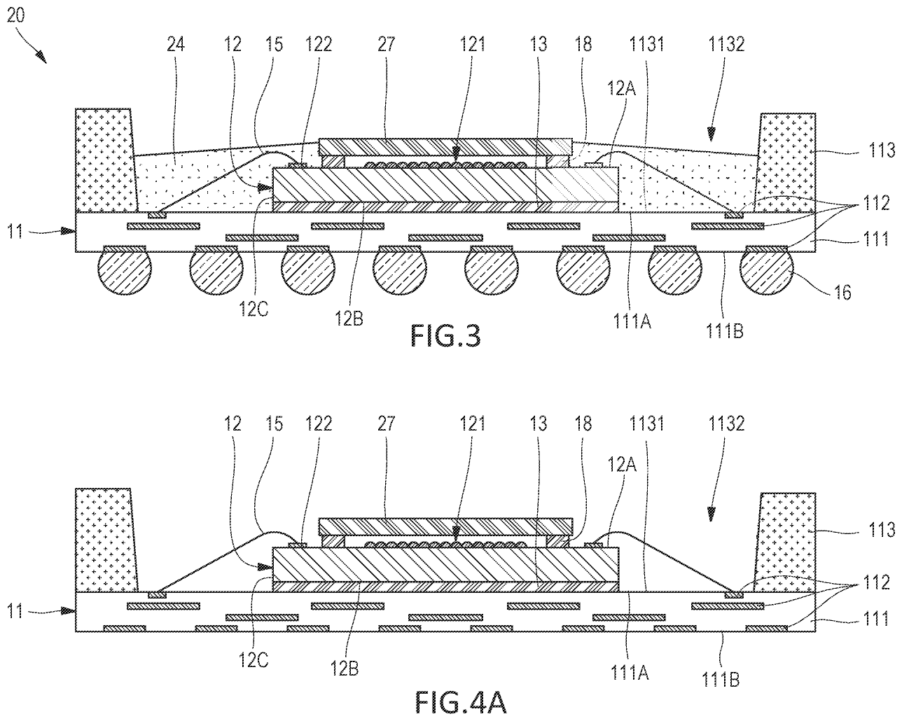

FIG. 3 shows a cross-sectional view an example electronic device 20. In the example shown in FIG. 3, electronic device 20 can comprise substrate 11, electronic component 12, adhesives 13 and 18, internal interconnects 15, external interconnects 16, encapsulant 24, and lid 27. In some examples, electronic device 20 can comprise similar elements, features, materials, or formation processes to those of electronic device 10 described above with reference to FIGS. 1 to 2G.

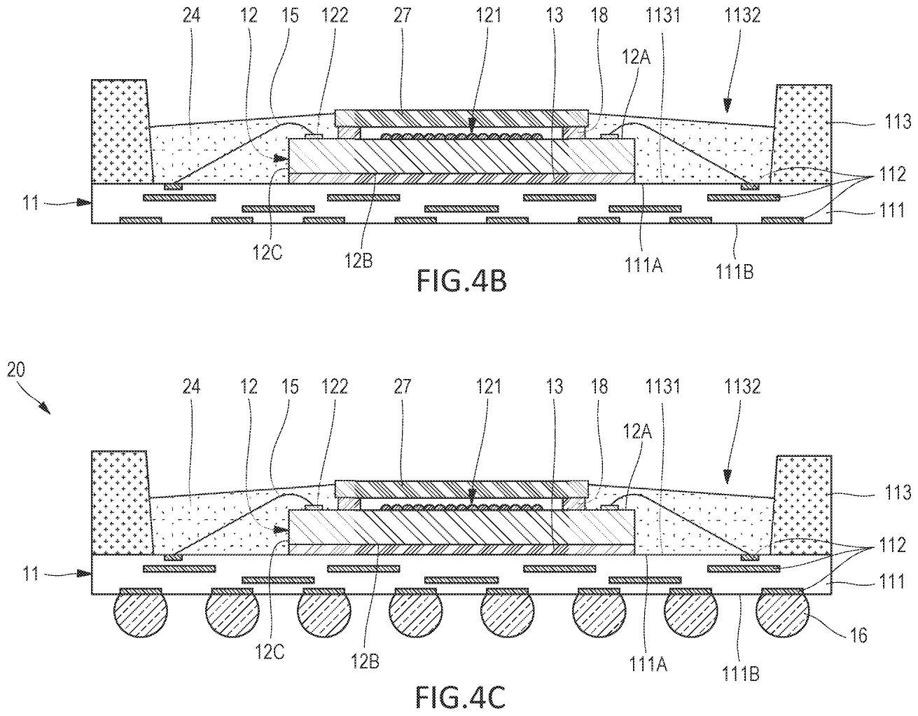

FIGS. 4A to 4C show cross-sectional views of an example method for manufacturing example electronic device 20.

FIG. 4A shows a cross-sectional view of electronic device 20 at an early stage of manufacture. In the example shown in FIG. 4A, the steps described with respect to FIGS. 2A to 2D can be followed, and then lid 27 can be provided on electronic component 12. Lid 27 can be coupled to the top side of electronic component 12. For example, adhesive 18 can couple lid 27 to electronic component 12. Lid 27 can cover transceiver module 121 of electronic component 12. In some examples, lid 27 can be positioned inside component terminals 122. For example, component terminals 122 may be located between lid 27 and the lateral sides of electronic component 12. Internal interconnects 15 can be connected to component terminals 122 located outside lid 27. In some examples, adhesive 18 can be provided between transceiver module 121 and component terminals 122 on electronic component 12, lid 27 can be seated on adhesive 18, and then adhesive 18 can be cured (for example, cured by UV), thereby coupling lid 27 to electronic component 12. In some examples, the area (or footprint) of the lid 27 can be smaller than the area (or footprint) of electronic component 12. In some examples, the area (or footprint) of the lid 27 can be greater than the area (or footprint) of transceiver module 121. In some examples, lid 27 can comprise similar elements, features, materials, or formation processes to those of lid 17 previously described.

FIG. 4B shows a cross-sectional view of electronic device 20 at a later stage of manufacture. In the example shown in FIG. 4B, encapsulant 24 can be provided within substrate cavity 1132. Encapsulant 24 can encapsulate substrate base 1131, internal interconnects 15, and electronic component 12. In some examples, encapsulant 24 can encapsulate (e.g., be located over) part of the top side of electronic component 12. In some examples, at least a portion of lid 27 (e.g., the top side of lid 27) can be exposed from encapsulant 24. In some examples, encapsulant 24 can contact the interior surface of substrate sidewall 113, the lateral sides of electronic component 12, and the lateral sides of lid 27. In some examples, encapsulating the lateral sides of lid 27 can fix or hold lid 27 in place over substrate 11. Extending encapsulant 24 to lid 27 can protect electronic component 12 from exposure to external factors or environments. In some examples, the thickness of encapsulant 24, as measured from the top side of substrate 11, can range from about 150 μm to about 2100 μm. In some examples, encapsulant 24 can comprise similar elements, features, materials, or formation processes to those of encapsulant 14 previously described.

FIG. 4C shows a cross-sectional view of electronic device 20 at a later stage of manufacture. In the example shown in FIG. 4C, external interconnects 16 can be provided on the bottom side of substrate 11.

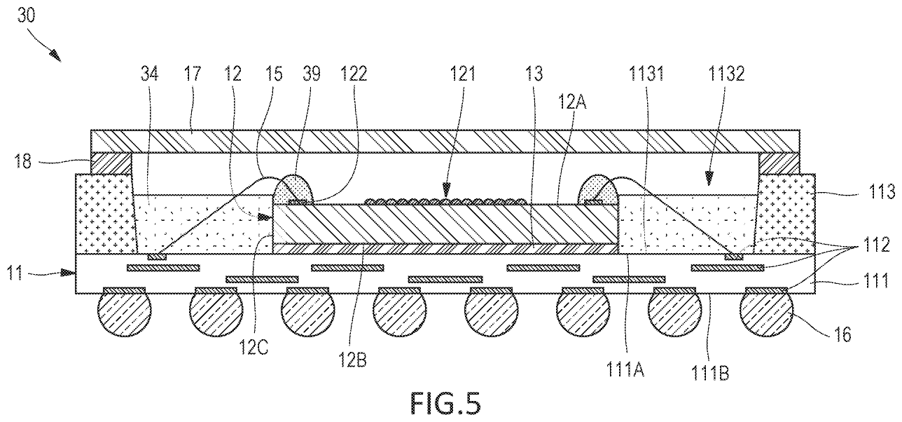

FIG. 5 shows a cross-sectional view an example electronic device 30. In the example shown in FIG. 5, electronic device 30 can comprise substrate 11, electronic component 12, adhesives 13 and 18, internal interconnects 15, external interconnects 16, lid 17, encapsulant 34, and dam 39. In some examples, electronic device 30 can comprise similar elements, features, materials, or formation processes to those of electronic device 10, as previously described.

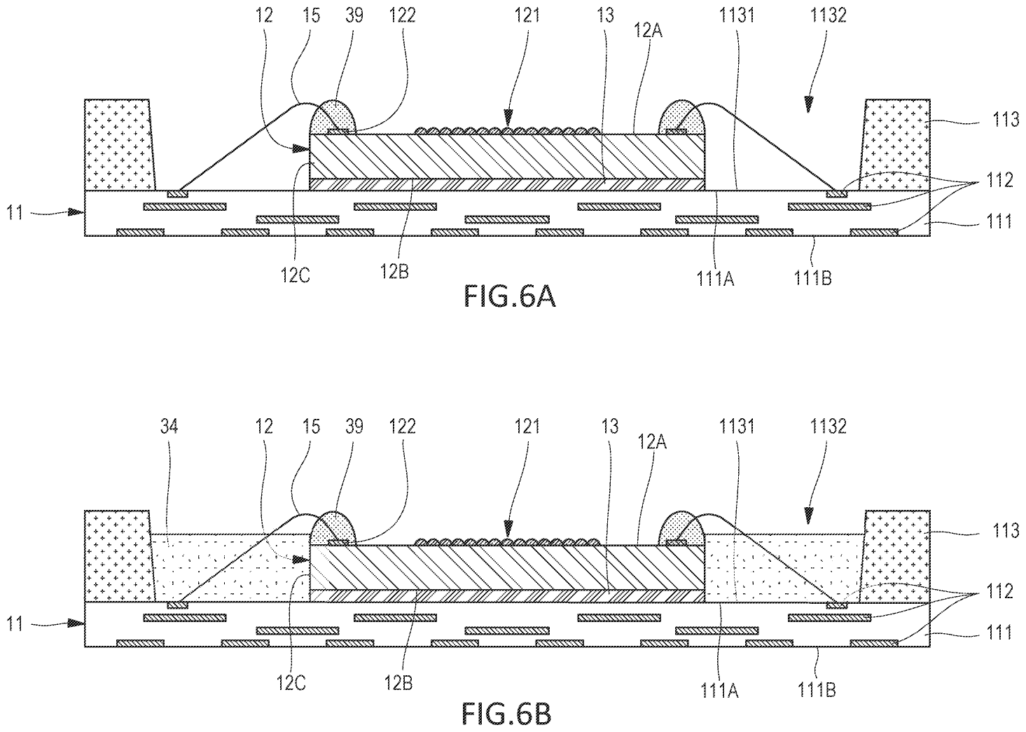

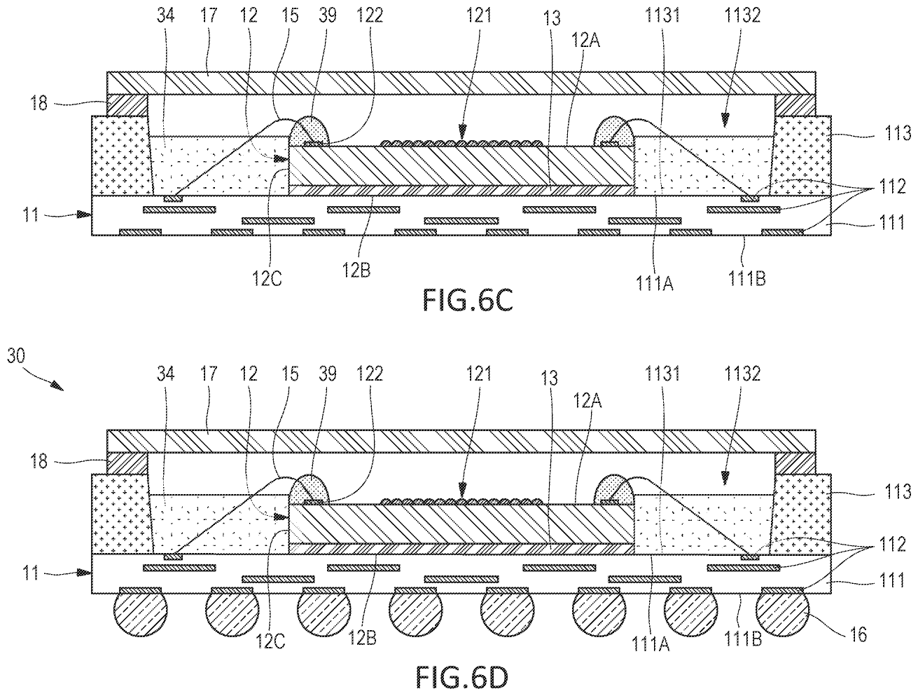

FIGS. 6A to 6D show cross-sectional views of an example method for manufacturing example electronic device 30.

FIG. 6A shows a cross-sectional view of electronic device 30 at an early stage of manufacture. In the example shown in FIG. 6A, the steps described with respect to FIGS. 2A to 2D can be followed, and then dam 39 can be provided on electronic component 12. Dam 39 can be provided on component terminals 122 where internal interconnects 15 are coupled. In some examples, dam 39 can cover component terminals 122 and part of internal interconnects 15. Dam 39 can be provided continuously or discontinuously at the edge of electronic component 12. In some examples, the lateral side of dam 39 can be positioned on the same line as the lateral side of electronic component 12 (e.g., dam 39 can extend to the lateral side 12C of electronic component 12). In some examples, dam 39 can prevent, or reduce, defects, such as copper dendrite growth on electronic component 12, which can cause reliability issues. In some examples, dam 39 can comprise or be referred to as epoxy, resin, polymer, a mold compound, a protective material, or a mold material. In some examples, the thickness of dam 39, as measured from the top side of electronic component 12, can range from about 100 μm to about 500 μm, and the width of dam 39, as measured in a direction parallel to the top side of electronic component 12, can range from about 100 μm to about 600 μm. In some examples, dam 39 can be a preformed structure and placed onto electronic component 12. In other examples, dam 39 can be formed using dispensing processes, 3D printing, or other processes as known to one of ordinary skill in the art.

FIG. 6B shows a cross-sectional view of electronic device 30 at a later stage of manufacture. In the example shown in FIG. 6B, encapsulant 34 can be provided within substrate cavity 1132. Encapsulant 34 can encapsulate substrate base 1131, part of internal interconnects 15, and the lateral sides of electronic component 12. In some examples, encapsulant 34 can contact substrate sidewall 113 and the lateral sides of electronic component 12. In some examples, encapsulant 34 can be at or proximal to an outer side of dam 39 (e.g., the side oriented away from or distal to electronic component 12). In some examples, encapsulant 34 encapsulates the lateral side 12C of electronic component 12 and a least a portion of dam 39 as illustrated in FIG. 6B. In some examples, dam 39 can block or prevent encapsulant 34 provided within substrate cavity 1132 from flowing over the top side 12A of electronic component 12. In some examples, the thickness of encapsulant 34, as measured from the top side of substrate 11, can range from about 160 μm to about 1000 μm. In some examples, encapsulant 34 can comprise similar elements, features, materials, or formation processes to those of encapsulant 14, as previously described.

FIG. 6C shows a cross-sectional view of electronic device 30 at a later stage of manufacture. In the example shown in FIG. 6C, lid 17 can be attached or coupled to substrate sidewall 113 through adhesive 18.

FIG. 6D shows a cross-sectional view of electronic device 30 at a later stage of manufacture. In the example shown in FIG. 6D, external interconnects 16 can be coupled to exposed portion of conductive structure 112 at the bottom side 11B of substrate 11. In some examples, electronic device 30 can use lid 27 similar to electronic device 20.

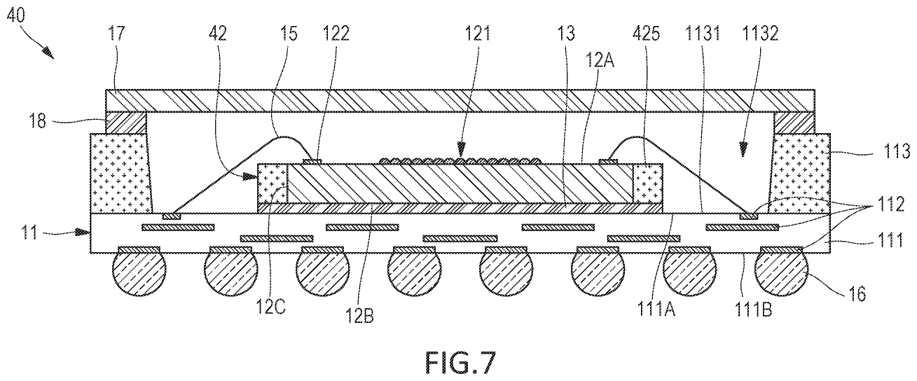

FIG. 7 shows a cross-sectional view an example electronic device 40. In the example shown in FIG. 7, electronic device 40 can comprise substrate 11, electronic component 42, adhesives 13 and 18, internal interconnects 15, external interconnects 16, and lid 17. In some examples, electronic device 40 can comprise similar elements, features, materials, or formation processes to those of electronic device 10, as previously described. Electronic component 42 can comprise transceiver module 121, component terminals 122, and component encapsulant 425. In some examples, electronic device 40 may be devoid of encapsulant 14 (FIG. 1) (e.g., internal interconnects 15 may be completely free of encapsulant and/or the entirety of each internal interconnect 15 extending between component terminal and conductive structure 112 may be exposed to air or otherwise devoid of encapsulant). Component encapsulant 425 is an example of an encapsulant.

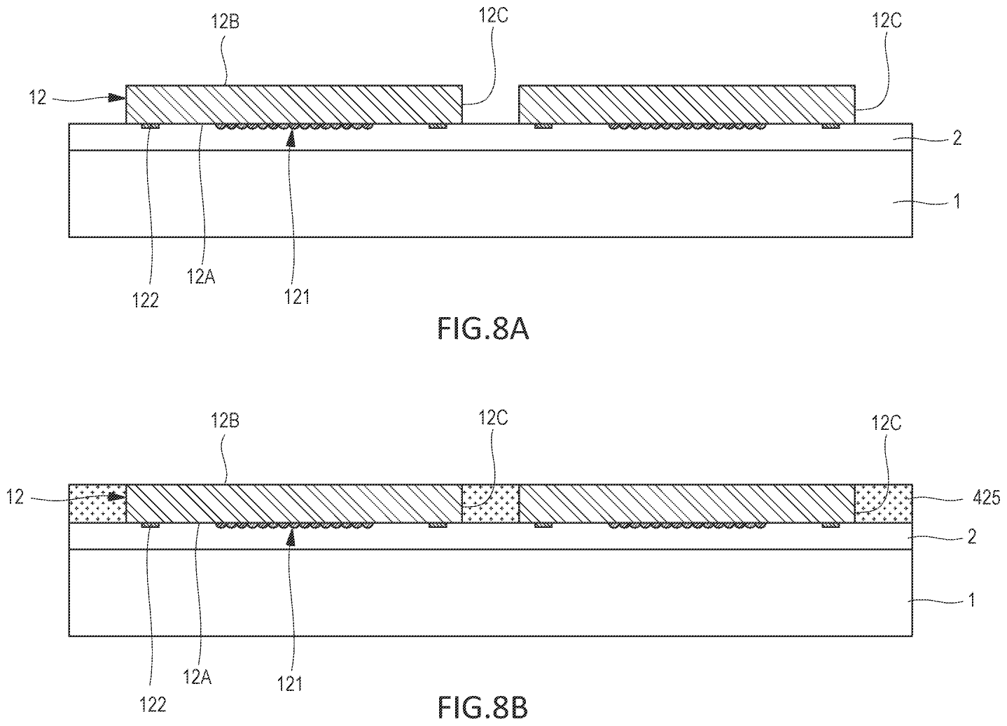

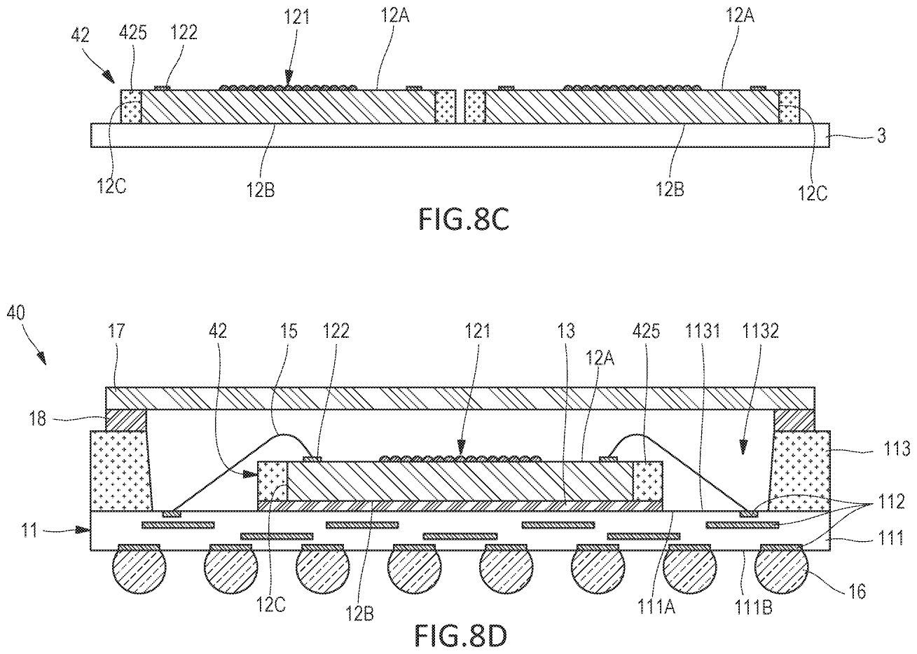

FIGS. 8A to 8D show cross-sectional views of an example method for manufacturing an example electronic device 40.

FIG. 8A shows a cross-sectional view of electronic device 40 at an early stage of manufacture. In the example shown in FIG. 8A, electronic components 12 can be provided on carrier 1. In some examples, electronic component 12 can be attached to carrier 1 through adhesive film 2. In some examples, carrier 1 can be composed of or referred to as a metal, silicon, glass, ceramic, or plastic wafer or panel. In some examples, carrier 1 can have a disk shape or a square (e.g., rectangular or square) plate shape. Carrier 1 can support electronic components 12 in later processes as described below. In some examples, adhesive film 2 can comprise a temporary adhesive film, a temporary adhesive tape, a thermal release tape, or an adhesive tape. In some examples, adhesive film 2 can be removed by heating, chemical materials, light irradiation, or physical force. In some examples, electronic components 12 be arranged on carrier 1 so as to be spaced apart from one another. In some examples, electronic component 12 may be oriented with transceiver module 121 and component terminals 122 toward or contacting adhesive film 2. That is, transceiver module 121 and component terminals 122 can be proximal to adhesive 2.

FIG. 8B shows a cross-sectional view of electronic device 40 at a later stage of manufacture. In the example shown in FIG. 8B, component encapsulant 425 can encapsulate (e.g., surround the lateral sides 12C of) electronic components 12. Component encapsulant 425 can be provided between electronic components 12. In some examples, the side 12B of electronic component 12 opposite carrier 1 can be exposed from component encapsulant 425. For example, component encapsulant 425 may be deposited over electronic component 12 and then a removal process, such as a grinding operation may be performed to remove a portion of component encapsulant 425 and expose electronic component 12. Component encapsulant 425 can cover or protect the lateral sides 12C of electronic component 12. In some examples, component encapsulant 425 can comprise or be referred to as epoxy, resin, polymer, a mold compound, a protective material, or a mold material. In some examples, the width of component encapsulant 425, as measured from a lateral side 12C of electronic component 12, can range from about 50 μm to about 500 μm.

FIG. 8C shows a cross-sectional view of electronic device 40 at a later stage of manufacture. In the example shown in FIG. 8C, carrier 1 and adhesive film 2 can be removed. In some examples, by removing adhesive film 2, electronic component 12 can be separated from carrier 1. In some examples, electronic components 12 can be coupled to each other by component encapsulant 425, thereby allowing electronic components 12 to be turned over and provided on carrier 3. In some examples, a singulation (e.g., dicing or sawing) process for separating electronic components 12 can be performed with electronic components 12 on carrier 3. In some examples, during singulation, electronic components 12 can be separated using a sawing tool, such as a diamond blade or a laser beam. In some examples, the sawing tool may cut through component encapsulant 425 to separate electronic components 12 into electronic components 42. That is, component encapsulant 425 comprises a singulated structure. In some examples, electronic component 12 and component encapsulant 425 can be referred to as electronic component 42.

FIG. 8D shows a cross-sectional view of electronic device 40 at a later stage of manufacture. In the example shown in FIG. 8D, electronic component 42 can be disposed on substrate base 1131 and in substrate cavity 1132. Internal interconnects 15 can be coupled to component terminals 122 of electronic component 42 and to conductive structure 112 of substrate 11. Lid 17 can be coupled to substrate sidewall 113 through adhesive 18. Component encapsulant 425 can protect electronic component 12 and can prevent, or reduce, defects, such as copper dendrite growth on electronic component 12. In some examples, adhesive 13 is interposed between encapsulant 14 and substrate base 1131 and interposed between the electronic component 12 and substrate base 1131. In some examples, portions of substrate base 1131 are devoid of encapsulant.

In some examples, electronic device 40 can comprise encapsulant 14 (FIG. 2E) on exposed portions of substrate base 1131 between substrate sidewall 113 and encapsulant 42. In such examples, encapsulant 14 can be referred to as a first encapsulant and encapsulant 42 can be referred to as a second encapsulant or vice versa. In some examples, electronic device 40 can use lid 27 and encapsulant 14 similar to electronic device 20. In some examples, electronic component 40 can include dam 39.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a substrate comprising:
a substrate first side;
a conductive structure; and
a substrate sidewall on the substrate first side;
wherein:
the substrate sidewall forms a perimeter;
the substrate first side within the perimeter defines a substrate base; and
the substrate sidewall and the substrate base form a substrate cavity;
an electronic component comprising:
a component first side;
a component second side opposite to the component first side; and
a component lateral side connecting the component first side to the component second side;
wherein:
the electronic component is disposed over a first portion of the substrate base within the substrate cavity and is coupled to the conductive structure;
an encapsulant encapsulating at least a portion of the component lateral side; and
a lid over at least a portion of the component first side;
wherein:
at least a portion of the component first side is devoid of the encapsulant.

2. The electronic device of claim 1, wherein:
the substrate sidewall comprises an interior surface;
and
the encapsulant extends to the interior surface.

3. The electronic device of claim 1, further comprising:
an internal interconnect coupled to the electronic component and the conductive structure.

4. The electronic device of claim 3, wherein:
the encapsulant encapsulates at least a portion of the internal interconnect.

5. The electronic device of claim 3, wherein:
the lid comprises a material configured to pass an optical signal;
the electronic component comprises a transceiver structure proximal to the component first side;
the lid is coupled to the component first side over the transceiver structure;
the encapsulant encapsulates the internal interconnect;
the encapsulant encapsulates at least a portion of the component first side; and
at least a portion of the lid is exposed from the encapsulant.

6. The electronic device of claim 5, further comprising:
an adhesive coupling the lid to the component first side;
wherein:
the lid comprises a lid lateral side;
the adhesive comprises an adhesive lateral side distal to the transceiver structure; and
the first encapsulant contacts the lid lateral side and the adhesive lateral side.

7. The electronic device of claim 1, wherein:
the lid comprises a material configured to pass an optical signal; and
the lid is coupled to the substrate sidewall.

8. The electronic device of claim 1, further comprising:
an adhesive coupling the electronic component to the first portion of the substrate base;
wherein:
the adhesive is interposed between the first encapsulant and the substrate base; and
a second portion of the substrate base is devoid of the encapsulant, the second portion extending from first portion to the substrate sidewall.

9. The electronic device of claim 1, further comprising:
a dam at an edge of the component first side proximate to the component lateral side;
wherein:
the encapsulant encapsulates at least a portion of the dam.

10. An electronic device, comprising:
a substrate comprising:
a substrate base;
a substrate sidewall at a perimeter of the substrate base; and
a conductive structure;
wherein:
the substrate base and the substrate sidewall define a substrate cavity;
an electronic component disposed over the substrate base in the substrate cavity and coupled to the conductive structure, the electronic component comprising a component first side distal to the substrate base and a component lateral side;
an encapsulant over at least a portion of the component lateral side, wherein at least a first portion of the component first side is free of the encapsulant; and
a lid overlying at least the first portion of the component first side.

11. The electronic device of claim 10, further comprising:
an internal interconnect coupled to the electronic component and the conductive structure;
wherein:
the substrate sidewall comprises an interior surface; and
the encapsulant is over at least a portion of the internal interconnect and over at least a portion of the interior surface.

12. The electronic device of claim 10, wherein:
the lid comprises a transmissive material; and
the lid is coupled to the substrate sidewall.

13. The electronic device of claim 10, wherein:
the lid comprises a transmissive material, a lateral side, and a top side;
the electronic component comprises a transceiver structure proximal to the component first side;
the encapsulant is over at least a portion of the component first side and over at least a portion of the lid lateral side; and
the lid top side is exposed from the encapsulant.

14. The electronic device of claim 10, further comprising:
an adhesive coupling the electronic component to the substrate base;
wherein:
the adhesive is interposed between the encapsulant and the substrate base; and
the substrate sidewall is devoid of the encapsulant.

15. The electronic device of claim 10, further comprising:
an internal interconnect coupled to a component terminal of the electronic component and the conductive structure; and
a dam disposed over the component terminal and a portion of the internal interconnect;
wherein:
the dam is proximate to the component lateral side;
and
the encapsulant is over the component lateral side and at least a portion of the dam.

16. A method of manufacturing an electronic device, comprising:
providing a substrate comprising:
a substrate base;
a substrate sidewall at a perimeter of the substrate base; and
a conductive structure;
wherein:
the substrate base and the substrate sidewall define a substrate cavity;
providing a first electronic component comprising a component first side, a component second side opposite to the component first side, and a component lateral side connecting the component first side to the component second side;
disposing the first electronic component over the substrate base and in the substrate cavity;
coupling an internal interconnect between the first electronic component and the conductive structure;
providing an encapsulant over at least a portion of the component lateral side; and
providing a lid overlying at least a first portion of the component first side.

17. The method of claim 16, wherein:
providing the substrate comprises providing the substrate sidewall with an interior surface;
and
providing the encapsulant comprises providing the encapsulant over at least a portion of the internal interconnect and over at least a portion of the interior surface of the substrate sidewall.

18. The method of claim 16, wherein:
providing the lid comprises:
providing the lid comprising a transmissive material; and
attaching the lid to the substrate sidewall.

19. The method of claim 16, wherein:
providing the first electronic component comprises providing a transceiver structure at the first portion of the component first side;
providing the lid comprises:
providing the lid comprising a transmissive material, a lateral side, and a top side; and
attaching the lid to the component first side overlying the transceiver structure; and
providing the encapsulant comprises:
providing the encapsulant over at least a portion of the component first side and over at least a portion of the lid lateral side, wherein the lid top side is exposed from the encapsulant.

20. The method of claim 16, wherein:
providing the first electronic component comprises:
providing a carrier;
providing the first electronic component as part of a plurality of electronic components, each of the plurality of electronic components having a component first side and a component lateral side;
coupling the component first side of the first electronic component to the carrier;
coupling the component first side of a second electronic component of the plurality of electronic components to the carrier laterally spaced apart from the first electronic component to provide a gap between the component lateral side of the first electronic component and the component lateral side of the second electronic component;
providing the encapsulant comprises providing the encapsulant in the gap adjacent to the component lateral side of the first electronic component and adjacent to the component lateral side of the second electronic component;
the method further comprises singulating through the encapsulant to separate the first electronic component from the second electronic component; and
coupling the first electronic component to the substrate comprises coupling with an adhesive interposed between the encapsulant and the substrate base and interposed between the component second side and the substrate base.
